(19) United States
(12) Patent Application Publication
(10) Pub. No.: US 2026/0322179 A1
(43) Pub. Date: Oct. 15, 2026

(54) DISCONNECT SWITCH MANAGEMENT IN A POWER RECEIVER

(71) Applicant: DOLBY INTELLECTUAL PROPERTY LICENSING, LLC

(72) Inventors: JAYANTI GANESH, Bengaluru (IN); VISWANATHAN KANAKASABAI, Bengaluru (IN); SUBBARAO TATIKONDA, Bengaluru (IN); Suma Memana NARAYANA BHAT, Bengaluru (IN)

(73) Assignee: DOLBY INTELLECTUAL PROPERTY LICENSING, LLC, (US)

(21) Appl. No.: 19/485,627

(22) PCT Filed: May 22, 2024
(86) PCT No.: PCT/US2024/030470

§ 371 Date: Nov. 18, 2025

(30) Foreign Application Priority Data
May 23, 2023 (IN) 202311035887

(51) Int. Cl. H02J 50/80; G01R 19/165; G01R 31/40; H02J 50/00; H02J 50/12

(52) U.S. Cl. CPC H02J 50/80; G01R 19/16538; G01R 31/40; H02J 50/001; H02J 50/12

(57) ABSTRACT

This disclosure provides systems, methods and apparatuses for a safety mechanism and related operations in an appliance having a Power Receiver (PRx) of a wireless power system. Aspects of this disclosure enable the Power Receiver to determine the status of the disconnect switch based on an electrical measurement of a relay coil of the disconnect switch. The Power Receiver can verify that the disconnect switch is in the closed position before transitioning to a power state. In some aspects, the Power Receiver can determine whether a harvested bias power is sufficient to close the disconnect switch before transitioning to the power state.

### TECHNICAL FIELD

This disclosure relates generally to wireless power and some aspects relate to a safety mechanism and related operations in a Power Receiver of a wireless power system.

### DESCRIPTION OF RELATED TECHNOLOGY

A wireless power system includes a Power Transmitter (PTx) and a Power Receiver (PRx). Inductive coupling can enable wireless power transfer between a primary coil of the Power Transmitter and a secondary coil of the Power Receiver. The primary coil of the Power Transmitter produces an electromagnetic field during a power state of the wireless power system. The electromagnetic field induces a voltage in the secondary coil of the Power Receiver when the secondary coil is present in the electromagnetic field. The Power Receiver can use the induced voltage (either directly or via a rectifier) to power a load. Example loads might include a motor, a heating element, electronics, or a power storage device, among other examples. In an example kitchen environment. a magnetic power source (such as a kitchen hob) might include one or more Power Transmitters. An appliance (such as a cordless kitchen appliance) might include a Power Receiver as well as the load. The appliance can be placed on a Power Transmitter such that the Power Receiver of the appliance can receive wireless power from the magnetic power source.

Some appliances are equipped with safety features to mitigate potential damage caused by a faulty Power Transmitter, an unexpected power surge, unintended powering, or a component failure in the Power Transmitter or the Power Receiver. The safety feature is intended to mitigate potential damage to the Power Receiver, other components of an appliance that contains the Power Receiver, or the operating environment of the appliance. An example safety feature is a switch, referred to as a “disconnect switch.” For example, the disconnect switch can be connected in series between one terminal of the secondary coil and another component (such as a rectifier of the Power Receiver or a load of the appliance). In a closed position (referred to as “closed”), the disconnect switch connects the load to the secondary coil. In an open position (referred to as “open”), the disconnect switch disconnects the load from the secondary coil. An appliance is configured to close the disconnect switch just before and during power transfer. At other times, the disconnect switch is normally open to disconnect the load.

In an emergency condition, the Power Receiver might open the disconnect switch to disable power reception. However, it has been discovered that opening the disconnect switch during a power state can cause high voltages to become temporarily induced across the disconnect switch. The high voltages or a failure of the disconnect switch can result in damage to the disconnect switch, the Power Receiver, the appliance, or the operating environment of the appliance. Therefore, it is desirable to ensure proper operation of the disconnect switch before and during the power state to prevent a condition in which the disconnect switch might be open during the power state.

### BRIEF SUMMARY

The systems, methods, and apparatuses of this disclosure each have several innovative aspects, no single one of which is solely responsible for the desirable attributes disclosed herein.

One aspect of this disclosure can be implemented as a method of a Power Receiver. The method includes obtaining an electrical measurement associated with a relay coil of a disconnect switch. The method includes monitoring a status of the disconnect switch based, at least in part, on the electrical measurement and a threshold value. The threshold value is an electrical quantity that corresponds with the relay coil successfully closing the disconnect switch.

Another aspect of this disclosure can be implemented as a method of a Power Receiver. The method includes receiving a communication signal from a Power Transmitter. The method includes harvesting bias power from the communication signal. The method includes controlling operation of the disconnect switch using the bias power based on whether an electrical quantity of the bias power is at or above a bias power threshold. The method includes communicating, to the Power Transmitter, a request for the Power Transmitter to increase power of the communication signal when the electrical quantity of the bias power is below the bias power threshold.

Details of one or more implementations of the subject matter described in this disclosure are set forth in the accompanying drawings and the description below. Other features, aspects, and advantages will become apparent from the description, the drawings, and the claims.

### BRIEF DESCRIPTION OF THE SEVERAL VIEWS OF THE DRAWINGS

Like reference numbers and designations in the various drawings indicate like elements. Note that the relative dimensions of the figures may not be drawn to scale.

FIG. 1 illustrates an example wireless power system.

FIG. 2 illustrates additional detail of an example Power Receiver with a disconnect switch.

FIG. 3 illustrates additional detail regarding a disconnect switch and a Power Receiver (PRx) controller.

FIG. 4 illustrates how an electrical measurement relates to the status of the disconnect switch.

FIG. 5 illustrates example operations of the Power Receiver to verify whether a bias power is sufficient to operate a disconnect switch.

FIG. 6 illustrates a flow chart with example operations of a Power Receiver.

FIG. 7 illustrates another flow chart with example operations of a Power Receiver.

FIG. 8 illustrates a block diagram of an example apparatus for use in a wireless power system.

### DETAILED DESCRIPTION

The following description is directed to certain implementations for the purpose of describing innovative aspects of this disclosure. However, a person having ordinary skill in the art will readily recognize that the teachings herein can be applied in a multitude of different ways. The described implementations can be implemented in any means, apparatus, system, or method for transmitting or receiving wireless power.

A wireless power system includes a Power Transmitter (PTx) and a Power Receiver (PRx). A Power Transmitter also may be referred to as a wireless power transmission apparatus. A Power Receiver also may be referred to as a wireless power reception apparatus. Some examples of this disclosure are based on a kitchen environment. For example, the Power Transmitter might be part of a magnetic power source such as a hob, a countertop, or range. In some implementations, the Power Transmitter may include a surface-mounted primary coil, an integrated primary coil, a countertop-mounted primary coil or a primary coil that is embedded or manufactured in a surface on which a Power Receiver can be placed. A Power Receiver includes a secondary coil configured to wirelessly receive power via inductive coupling with the primary coil of the Power Transmitter. The Power Receiver might be part of a cordless appliance such as a cordless blender, kettle, toaster, or cooking vessel, among other examples. Although the examples of this disclosure refer to a wireless power system in a kitchen environment, the disclosed techniques can be used with other types of wireless power systems or in other types of environments.

Typically, a cordless appliance includes a disconnect switch. The disconnect switch is a safety mechanism of an appliance to prevent unintended powering and activation of the appliance. The disconnect switch might be connected in series with a terminal of the secondary coil. The disconnect switch is typically opened or closed based on the operating state of the wireless power system. For example, the disconnect switch is closed just before and during a power state to enable power reception via the secondary coil. Conversely, the disconnect switch is open during pre-power states to prevent power reception via the secondary coil. While it is possible for the Power Receiver to intentionally open the disconnect switch during the power state, doing so can result in high voltages at the disconnect switch and could result in damage to the disconnect switch, other components of the appliance, or even the operating environment of the appliance. Therefore, the disconnect switch should only be intentionally opened during the power state in an emergency fault condition (such as overvoltage or overcurrent). Absent an emergency fault condition, the Power Receiver maintains the disconnect switch in a closed position beginning just before the power state and throughout the power state.

The disconnect switch includes a relay coil and a circuit connecting component (such as a lever, plunger, or other electromechanical element). Before the power state, the disconnect switch is in the open position (as a default position) and the circuit connecting component is disconnected from a terminal of the secondary coil. To move the disconnect switch to the closed position, the Power Receiver sends a switch control signal to apply power to the relay coil which in turn moves the circuit connecting component. While the relay coil is powered, the circuit connecting component connects the terminal of the secondary coil to other components of the Power Receiver, thereby enabling current to flow through the secondary coil and the other components.

This disclosure provides systems, methods and apparatuses for managing a disconnect switch in a Power Receiver of a wireless power system. Aspects of this disclosure enable the Power Receiver to determine the status (either “open” or “closed”) of the disconnect switch. The Power Receiver can determine and monitor the status of the disconnect switch based on an electrical measurement. The Power Receiver can compare the electrical measurement to a threshold value to determine the status of the disconnect switch. The threshold value can be an amount of the electrical measurement that corresponds with a relay coil of the disconnect successfully closing the circuit connecting component of the disconnect switch. Thus, the Power Receiver can determine that the disconnect switch is open when the electrical measurement is below a threshold value. The Power Receiver can determine that the disconnect switch is closed when the electrical measurement is at or above the threshold value. Thus, the techniques of this disclosure enable the Power Receiver to monitor the status of the disconnect switch based on the electrical measurement and the threshold value. Absent the techniques of this disclosure, a Power Receiver might not have a mechanism to verify that the disconnect switch is actually in the closed position after sending the switch control signal. In accordance with aspects of this disclosure, the Power Receiver can verify that the disconnect switch is in the closed position before transitioning to the power state.

In some examples, the electrical measurement is a relay coil current and the threshold value is based on the holding current of the disconnect switch. The holding current refers to the amount of current needed for the relay coil of the disconnect switch to keep the circuit connecting component in the closed position. When the Power Transmitter measures a relay coil current that is below the holding current, the Power Transmitter can determine that the disconnect switch is open. Conversely, when the relay coil holding currents is at or above the holding current, the Power Transmitter can determine that the disconnect switch is closed. Although the examples of this disclosure might refer to relay coil current and holding current, the techniques can be used with other types of electrical measurements and corresponding threshold values. For example, the electrical measurement might be a control voltage of the switch control signal applied to the relay coil and the threshold value might be an activation voltage of the relay coil. Activation voltage refers to the amount of voltage needed for the relay coil to move and keep the circuit connecting component in the closed position. Alternatively, the electrical measurement might be the power of the switch control signal and the threshold value might be an activation power of the relay coil. For brevity, examples of this disclosure refer to the relay coil current and the holding current.

In some aspects. the Power Receiver initially moves the disconnect switch to the closed position using bias power. The bias power is harvested from a communication signal received from the Power Transmitter. According to aspects of this disclosure, the Power Receiver can determine whether the bias power is sufficient to close the disconnect switch. For example, the Power Receiver can compare an electrical quantity of the bias power to a bias power threshold. The bias power threshold is associated with a power or voltage requirement to achieve the threshold value of the relay coil of the disconnect switch in addition to other pre-power operations of the Power Receiver. For example, the electrical quantity of the bias power might be a voltage of the bias power (sometimes referred to as bias power voltage or bias voltage), and the bias power threshold might be a voltage level needed to generate the relay coil current. Although examples of this disclosure refer to the voltage of the bias power as the described electrical quantity, the techniques can be applied to another electrical quantity of the bias power, such as current or power.

In some cases, the bias power is insufficient to close the disconnect switch. For example, misalignment of the Power Receiver and the Power Transmitter might reduce the bias power that is harvested by the Power Receiver. Additionally, or alternatively, the bias power might be limited by interference, environmental factors, or faulty components of the wireless power system. If the bias power has an electrical quantity below the bias power threshold, the Power Receiver might not be capable of reliably closing the disconnect switch. In aspects of this disclosure, the Power Receiver can manage operation of the disconnect switch based on whether the bias power has an electrical quantity (such as bias voltage) that is above the bias power threshold. In some implementations, the Power Receiver can communicate a request to the Power Transmitter to increase the power of the communication signal so that the Power Receiver can harvest more bias power from the communication signal. In some instances, the Power Transmitter reaches a maximum power for the communication signal such that the Power Transmitter cannot increase the power of the communication signal. The Power Transmitter might communicate a PTx status indication that indicates the Power Transmitter is using a maximum power for the communication signal. If the Power Receiver determines that the harvested bias power is still below the bias power threshold, the Power Receiver might indicate a fault condition via a user interface of the Power Receiver and refrain from entering the power state.

Particular implementations of the subject matter described in this disclosure can be implemented to realize one or more of the following potential advantages. The disclosed techniques enable the Power Receiver to determine the status of the disconnect switch accurately. Absent the disclosed techniques, there might be no reliable way for the Power Receiver to confirm the actual position of the disconnect switch after sending the switch control signal. With the ability to determine the status of the disconnect switch based on an electrical measurement and the threshold value, the Power Receiver can ensure that the switch is closed before transitioning to the power state. Furthermore, the Power Receiver can manage the operation of the disconnect switch based on the bias power and refrain from entering the power state if the bias power is insufficient to actually close the disconnect switch. Thus, the Power Receiver can ensure the disconnect switch reliable operates to achieve the intended function of safeguarding against potential issues or hazards. Furthermore, the Power Receiver can prevent repeated on/off (also referred to as “chattering” or “bouncing”) of the disconnect switch that might otherwise occur due to insufficient bias power. Chattering can cause damage to the Power Receiver-thus, a potential technical advantage of the disclosed subject matter is that damage can be prevented and the lifespan of the Power Receiver can be extended.

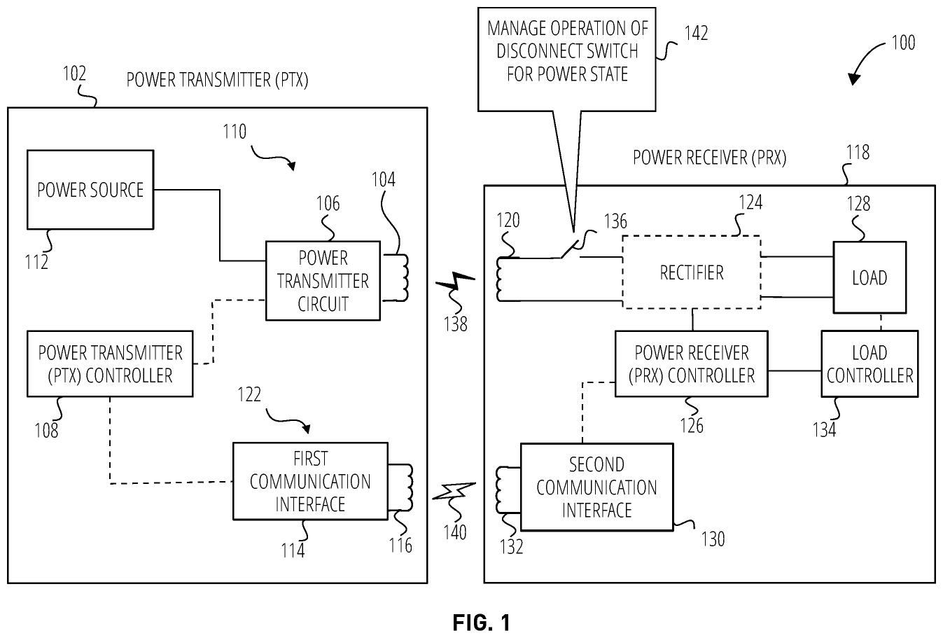

FIG. 1 illustrates an example wireless power system 100. The example wireless power system 100 includes a Power Transmitter 102 and a Power Receiver 118. In FIG. 1. dashed lines represent communications to distinguish from the solid lines that represent electrical circuit lines. The Power Transmitter 102 includes a primary coil 104 and a PTx controller 108. The primary coil 104 may be associated with a power transmitter circuit 106 (sometimes also referred to as a power signal generator, or a driver circuit, or a driver). The primary coil 104 may be a wire coil which transmits wireless power (which also may be referred to as wireless energy) via a wireless power signal 138. The primary coil 104 may transmit wireless energy using an inductive or a resonant magnetic field. The power transmitter circuit 106 may include components (not shown) to prepare the wireless power. For example, the power transmitter circuit 106 may include one or more switches, drivers, series capacitors, rectifiers, inverters, or other components. In some implementations, the power transmitter circuit 106, PTx controller 108 and other components (not shown) may be collectively referred to as a power transmitter unit 110. Some or all of the power transmitter unit 110 may be embodied as an integrated circuit (IC) that implements features of this disclosure. The PTx controller 108 may be implemented as a microcontroller, dedicated processor, integrated circuit, application specific integrated circuit (ASIC) or any other suitable electronic device.

A power source 112 provides power to the power transmitter unit 110. In some implementations, the power source 112 may convert alternating current (AC) power to direct current (DC) power. For example, the power source 112 may include a converter that receives an AC power from an external power supply and converts the AC power to a DC power used by the power transmitter circuit 106. Alternatively, or additionally, a component (such as an inverter) of the power transmitter circuit 106 may convert the DC power to the AC power. The power source 112 may be integrated as part of the Power Transmitter 102 or may be external to the Power Transmitter 102. In some implementations, the Power Transmitter 102 causes the power source 112 to regulate the DC output voltage of the power source 112. For example, the PTx controller 108 can set DC voltage of the power source 112 based on information (such as a value indicating a requested power) received from the Power Receiver 118. The Power Transmitter 102 can receive power configuration information from the Power Receiver 118 and use the information to set a parameter (such as the DC output voltage of the power source 112). The Power Transmitter 102 can receive the power configuration information during various operating states, such as the discovery state or power state. In some implementations, the Power Transmitter 102 includes a DC-DC converter (not shown) between the power source 112 and the Power Transmitter circuit 106 to control the variable DC output voltage.

The PTx controller 108 is connected to a first communication interface 114. The first communication interface 114 is connected to a first communication coil 116. In some implementations, the first communication interface 114 and the first communication coil 116 may be collectively referred to as the first communication unit 122. In some implementations. the first communication unit 122 may support short-range radio frequency communication, such as Near-Field Communication (NFC) or Bluetooth (BT). NFC is a technology by which data transfer occurs on a carrier frequency of 13.56 Megahertz (MHz). The first communication unit 122 also may support any suitable communication protocol. The first communication unit 122 may contain modulation and demodulation circuits to transmit a communication signal 140 via the first communication coil 116. Alternatively, or additionally, the PTx controller 108 may use frequency, amplitude, current, or voltage modulation of the wireless power signal 138 to communicate via an in-band communication link (not shown) that includes the primary coil 104.

The Power Receiver 118 may include a secondary coil 120, a rectifier 124, a PRx controller 126, a second communication interface 130, a load controller 134, a load 128, and a memory (not shown). In some implementations, the load 128 can include a driver (not shown) for controlling at least one parameter such as charging current, speed, or torque of the load. In some implementations, the rectifier 124 may be omitted such as when the voltage induced in the secondary coil 120 can directly power the load 128. Although not shown, a load capacitance can be used after the rectifier 124 to filter the high frequency component of the rectifier voltage. Although shown as different components, some components may be packaged or implemented in the same hardware. For example, in some implementations, the PRx controller 126 and the load controller 134 may be implemented as a single controller. The PRx controller 126, the load controller 134, or any combination thereof, may be implemented as a microcontroller, dedicated processor, integrated circuit, application specific integrated circuit (ASIC) or any other suitable electronic device.

The PTx controller 108 may detect the presence or proximity of a Power Receiver 118. This detection may happen during a periodic pinging process of the first communication interface 114. During the pinging process, the first communication interface 114 also may supply power to the second communication interface 130 when the Power Receiver 118 is in proximity to the Power Transmitter 102. The second communication interface 130 may “wake up” and power-up the PRx controller 126 and may send a reply signal back to the first communication interface 114. Prior to power transfer, a handshaking process may take place during which the PTx controller 108 may receive identification and configuration data, among other information. from the Power Receiver 118. The PTx controller 108 may control characteristics of the wireless power signal 138 it provides to the Power Receiver 118 based on the configuration data.

The Power Receiver 118 might include a power harvester (not shown) capable of harvesting bias power from the communication signal 140. The power harvester might be included in the second communication interface 130 or might be coupled to the second communication coil 132. The power harvester can harvest bias power and provide the bias power to the PRx controller 126 and/or the load controller 134 to enable those components to function before wireless power transfer occurs. Once wireless power transfer occurs, the bias power might be obtained from the secondary coil 120 via the rectifier 124 or other bias power harvester (not shown) that can harvest the bias power from the wireless power signal 138.

A PRx controller 126 may be operationally coupled to the rectifier 124 and the second communication interface 130. The second communication interface 130 may contain modulation and demodulation circuits to wirelessly communicate via the second communication coil 132. Thus, the PRx controller 126 may wirelessly communicate feedback information to the PTx controller 108 via the second communication interface 130 to the first communication interface 114 using short-range radio frequency communication, such as NFC. Alternatively, or additionally, the PRx controller 126 may use load modulation to communicate via an in-band communication link (not shown) that includes the secondary coil 120.

A load controller 134 may be operationally coupled to the load 128 and the second communication interface 130. The load controller 134 may detect changes to load states such as change in charging currents in a battery charging application. The load controller 134 also may determine a load voltage reference. The load controller 134 also may send load voltage references, load current, and any other suitable information to the PRx controller 126 or the second communication interface 130 for communication to the Power Transmitter 102. The PRx controller 126 may additionally determine and provide feedback information indicating a measured load voltage available to the load 128. In some feedback messages, the feedback information may include a reference voltage indicating a required voltage for the load 128, an error in the output voltage of the load 128, or the required power for the load. Although the PRx controller 126 and load controller 134 are shown separately, they may be included in the same component of the Power Receiver 118.

The Power Transmitter 102 and the Power Receiver 118 might operate according to wireless power specification. The wireless power specification might include a state diagram that describes the operating states in which the wireless power system may operate. There can be four operating states associated with the wireless power system: a standby state (sometimes also referred to as a ping phase), a discovery state (sometimes referred to as an identification phase), a connected state, and a power state (sometimes referred to as a power transfer phase). The wireless power system typically begins in the standby state until the Power Transmitter detects a Power Receiver. In the discovery state, the Power Transmitter establishes communication and receives the first identification information of the Power Receiver and its static configuration data. In the connected state and the power state, the Power Transmitter and Power Receiver exchange information to agree and adjust parameters related to wireless power transfer. The system can move to a reinitialization state as needed to reinitialize or return to the standby state when communication, powering, or other activities are no longer taking place. Each of the operating states are briefly described herein for reference.

In the standby state, the Power Transmitter tries to establish communications with a Power Receiver. The Power Receiver may be just placed on the interface surface or may not be present during this operating state. The Power Transmitter may attempt to communicate or detect the presence of the Power Receiver. For example, the Power Transmitter may use an analog ping, out-of-band communication (such as NFC), a digital ping, or any combination thereof, to determine that a compatible Power Receiver is present. Once the wireless power system determines that a Power Receiver is present (such as by confirming NFC communication), the wireless power system may transition to the discovery state 204.

In the discovery state, the Power Receiver may establish communication with the Power Transmitter and send static configuration information (such as identification and configuration information) to the Power Transmitter. For example, the Power Transmitter may retrieve static configuration information from the Power Receiver via the NFC communication. The Power Transmitter and the Power Receiver may use this information to verify that they both use compatible versions of a technical specification or protocol for wireless power transfer. The Power Transmitter and Power Receiver may communicate basic settings or communicate regarding their respective capabilities. From the discovery state 204. the wireless power system may transition to the connected state.

In the connected state, the Power Transmitter and the Power Receiver may exchange further communications to negotiate the parameters that govern the power state. For example, a power negotiation can occur during the connected state. After negotiating the parameters, the Power Transmitter may be prepared to transfer wireless power and the Power Receiver may be prepared to receive the wireless power. However, the Power Transmitter may wait for a request or command from the Power Receiver before transitioning to the power state. This may be useful, for example, when a cordless appliance (such as a blender, toaster, mixer, or microwave, among other examples) is configured for use pending a user interaction. The user may initiate the power state a user interface (such as an activation switch) of the Power Receiver, which in turn communicates to the Power Transmitter to transition to the power state.

Cordless appliances are equipped with a disconnect switch 136 that is operated in conjunction with the operating states. For example, the disconnect switch 136 might be maintained in an open position to prevent the flow of current to the load 128 when the Power Receiver 118 is in the pre-power states (the standby state, the discovery state, and the connected state). Before transitioning to the power state, the PRx controller 126 might cause the disconnect switch 136 to move to a closed position to enable the flow of current to the load 128.

The techniques of this disclosure enable the Power Receiver 118 to manage 142 operation of the disconnect switch 136. For example, the Power Receiver 118 can monitor the status of the disconnect switch 136 to verify that it is closed before and during the power state. Furthermore, the Power Receiver 118 can control operation of the disconnect switch 136 based on an amount of bias power harvested from the communication signal 140 before the power state. For example, if the bias power is insufficient to close the disconnect switch 136, the Power Receiver 118 might refrain from transitioning to the power state.

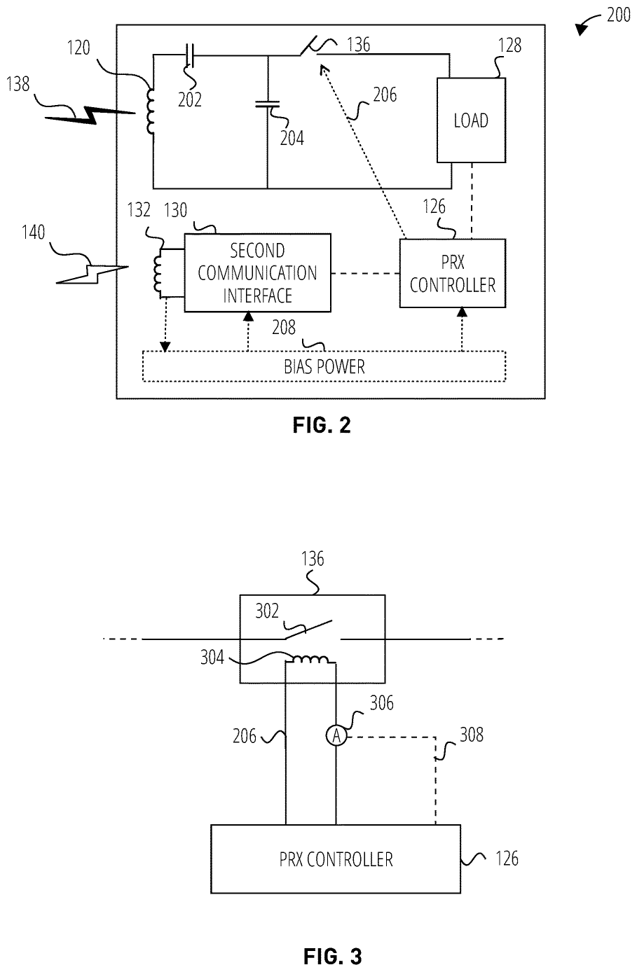

FIG. 2 illustrates additional detail of an example Power Receiver 200 with a disconnect switch 136. The example Power Receiver 200 may be an example of the Power Receiver 118 described with reference to FIG. 1. The Power Receiver 200 may be included in an appliance. The Power Receiver 200 might include a load 128 or the load 128 may be component of the appliance that also includes the Power Receiver 200.

The Power Receiver 200 includes a secondary coil 120, a second communication coil 132, a second communication interface 130, and a PRx controller 126 as described with reference to FIG. 1. In some implementations, the Power Receiver 200 may or may not include a rectifier (not shown in FIG. 2). FIG. 2 also shows a series capacitor 202 that may be coupled to one or more terminals of the secondary coil 120. The example Power Receiver 200 includes a disconnect switch 136 connected in a series between one of the terminals of the secondary coil 120 and the load 128. The disconnect switch 136 may be connected before or after the series capacitor 202 when the series capacitor 202 is present on that terminal. Although the disconnect switch 136 is shown as being connected in series, other configurations are possible. For example, instead of a single series switch (such as the disconnect switch 136 shown in FIG. 2), the Power Receiver 200 may include first and second disconnect switches (not shown) connected in series between both terminals of the secondary coil 120. A first disconnect switch (not shown) may be connected in series to a first terminal of the secondary coil 120 while a second disconnect switch (not shown) may be connected in series to a second terminal of the secondary coil 120. The first and second disconnect switches may be collectively referred to as a disconnect switch.

As described herein, the disconnect switch 136 should be closed before entering a power state. Therefore, the disconnect switch 136 is closed using bias power 208 harvested from the communication signal 140. The PRx controller 126 sends a switch control signal 206 to the disconnect switch 136 to cause the disconnect switch 136 to close. For example, the switch control signal 206 might have a nominal voltage (such as 5 volts(V)) and a nominal current (such as approximately 20 milli Amperes (mA)). If the switch control signal 206 has enough voltage and current, the resulting power will cause a relay coil of the disconnect switch 136 to move a circuit connecting component to a closed position. The disconnect switch 136 is said to be in the closed position when the circuit connecting component is in the closed position.

Absent the techniques of this disclosure, the PRx controller 126 might not verify that the disconnect switch 136 is in the closed position. For example, the PRx controller 126 might send the switch control signal 206 and simply wait for a period of time before sending a power request for the Power Transmitter to move to the power state and begin power transfer. This can potentially lead to a dangerous or damage-causing situation if the disconnect switch 136 is not actually in the closed position before the wireless power signal 138 induces high voltages on the secondary coil 120. To avoid these dangerous or damage-causing situations, the PRx controller 126 might verify that the disconnect switch 136 is actually in the closed position before communicating the power request. In some implementations, if the bias power 208 is insufficient, the power of the switch control signal 206 might be inoperative to close the disconnect switch 136. Thus, in some implementations. the PRx controller 126 can request additional power of the communication signal 140 to increase the bias power or might refrain from sending the switch control signal 206 if the bias power is below a bias power threshold.

FIG. 3 illustrates additional detail regarding a disconnect switch 136 and a PRx controller 126. For brevity, other components of the Power Receiver are omitted from FIG. 3. Nonetheless the disconnect switch 136 and the PRx controller 126 described with reference to FIG. 3 would be included in a Power Receiver, such as the Power Receiver 118 or the Power Receiver 200 described with reference to FIG. 1 and FIG. 2, respectively.

The disconnect switch 136 includes a relay coil 304 and a circuit connecting component 302. The circuit connecting component 302 might be a lever, plunger, or other electromagnetically-controller element. The circuit connecting component 302 has a default open position (as shown in FIG. 3). When voltage is applied to the relay coil 304, the relay coil 304 creates an electromagnetic field that moves the circuit connecting component 302 to a closed position. The PRx controller 126 sends a switch control signal 206 to the relay coil 304 to cause the relay coil 304 to generate the electromagnetic field. When the switch control signal 206 has a sufficient amount of power, the relay coil 304 will generate sufficient electromagnetic field to move the circuit connecting component 302. In some aspects, if the switch control signal 206 has sufficient power to generate a relay coil current above the holding current of the relay, the circuit connecting component 302 (and thus the disconnect switch 136) will be in a closed position. The holding current of the disconnect switch 136 might be inherent in the design and manufacturing of the disconnect switch 136.

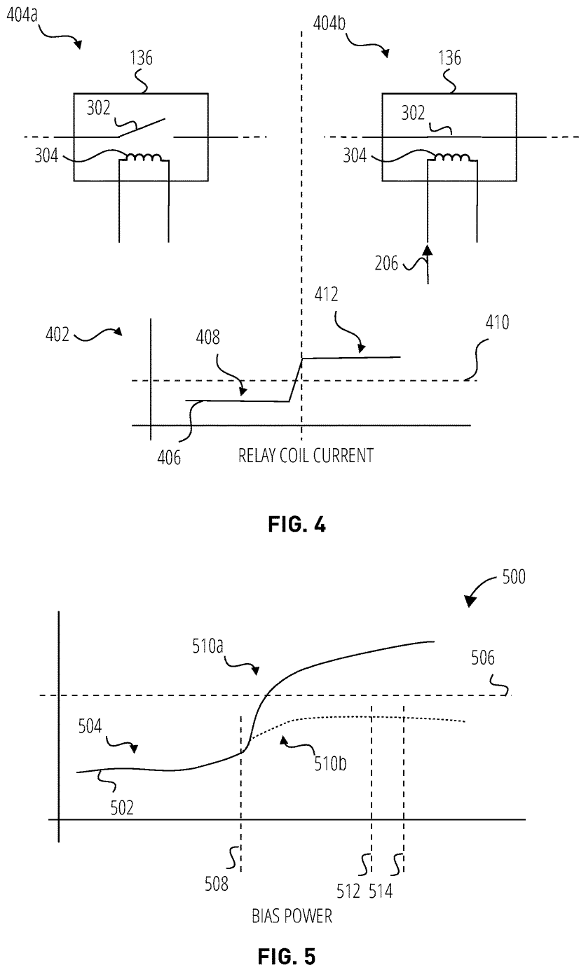

In accordance with aspects of this disclosure, a Power Receiver can include a sensor 306 in a circuit that includes the relay coil 304. The PRx controller 126 can obtain an electrical measurement 308 from the sensor 306. The electrical measurement 308 is indicative of an amount of electricity (such as current, voltage, or power) flowing through the relay coil 304. As described further with reference to FIG. 4, the PRx controller 126 can use the electrical measurement to determine the status of the disconnect switch 136. If the disconnect switch 136 is operating properly, when the switch control signal 206 is applied to the relay coil 304, the electrical measurement 308 will indicate an electrical measurement above a threshold value. The threshold value might be a holding current, an activation voltage, or other electrical property associated with the relay coil 304 successfully closing the circuit connecting component 302. If the electrical measurement is below the threshold value, that could mean that the relay coil 304 has failed, potentially resulting in the circuit connecting component 302 being in the open position.

In some implementations, the sensor 306 is a current sensor and the electrical measurement 308 is a measured relay coil current. The threshold value might be a holding current that corresponds to the amount of relay coil current needed to close the circuit connecting component 302.

In some implementations, the sensor 306 is a voltage sensor and the electrical measurement 308 is a measured control voltage of the switch control signal 206 applied to the relay coil 304. In such designs, the sensor 306 might measure the control voltage as a difference between the voltage of the switch control signal 206 and a neutral ground. In some implementations, the Power Receiver might translate the measured control voltage to a relay coil current. For example, as the relay coil resistance is a known fixed quantity, the relay coil current can be estimated based on the control voltage.

FIG. 4 is an illustration showing how on electrical measurement relates to the status of the disconnect switch. A plot diagram 402 shows the steady-state current through the relay coil 304 with and without sufficient power to close the disconnect switch 136. By measuring the electrical measurement 406 and comparing the electrical measurement 406 to a threshold value 410, the PRx controller can determine whether the disconnect switch 136 is in the open position (as shown on the left side 404a of FIG. 4) or in the closed position (as shown on the right side 404b of FIG. 4).

On the left side 404a, a low electrical measurement 408 is below the threshold value 410. For example, the low electrical measurement 408 might indicate no or insufficient relay coil current through the relay coil 304. Alternatively, the low electrical measurement 408 might indicate no or low control voltage (of an absent or insufficient switch control signal) being applied to the relay coil 304. Because the low electrical measurement 408 is below the threshold value 410. the Power Receiver can determine that the circuit connecting component 302 is in the open position.

On the right side 404b of FIG. 4, the switch control signal 206 is applied to the disconnect switch 136 and the control voltage of the switch control signal 206 is adequate to cause the relay coil 304 to close the circuit connecting component 302. The electrical measurement 406 might be a high electrical measurement 412 (being higher than the threshold value 410). Thus, the PRx controller can determine that the circuit connecting component 302 is in the closed position when the electrical measurement 406 (shown at high electrical measurement 412) is above the threshold value 410.

FIG. 5 illustrates example operations of the Power Receiver to verify whether a bias power is sufficient to operate a disconnect switch. FIG. 5 shows a bias power plot diagram 500 as an example how the Power Receiver might operate (or not operate) the disconnect switch based on the bias power 502 harvested from communication signals of the Power Transmitter. If the bias power 502 has an electrical quantity (such as voltage, current, or power) that is below a bias power threshold 506, the Power Receiver might not have sufficient bias power to ensure that the disconnect switch actually closes when the switch control signal is sent to the disconnect switch. The bias power threshold 506 might be based on a power or voltage requirement for operating the disconnect switch as well as for operating other components of the Power Receiver (such as the current sensor, the PRx controller, and the communication interface of the Power Receiver).

In the example scenario illustrated in FIG. 5, the initial electrical quantity of the bias power 504 is below the bias power threshold 506. At a first time (shown as t1 508), the Power Receiver might communicate a request for the Power Transmitter to increase power of the communication signals. As a result, the Power Transmitter might increase the power of the communication signals and thus the harvested bias power increases. As a result, the subsequent electrical quantity of the bias power 510a is above the bias power threshold 506 and the Power Receiver has sufficient bias power to operate the disconnect switch. In such cases, the Power Receiver can attempt to close the disconnect switch before transitioning to the power state.

In some instances, the Power Transmitter might not increase the power of the communication signals to a level sufficient for the Power Receiver to harvest bias power above the bias power threshold 506. For example, the Power Transmitter might already be at a maximum transmission power. As a result, the bias power might have an insufficient electrical quantity of the bias power 510b. Shown as a dotted line, the insufficient electrical quantity of the bias power 510b is below the bias power threshold 506. In this scenario, the Power Receiver will refrain from entering the power state. For example, the Power Receiver might refrain from sending the switch control signal and might refrain from sending a power request or power state transition request. In some implementations, the Power Receiver might send another request to increase the power of the communication signal until the power of the communication signal is sufficient for the harvested bias power to satisfy the bias power threshold 506.

In some implementations, the Power Transmitter can reach a maximum power for the communication signal without providing sufficient bias power for the Power Receiver to operate the disconnect switch. For example, at a second time (shown as t2 512), the Power Transmitter communicates a PTx status indication to indicate that the Power Transmitter is at the maximum power for the communication signal. Because the insufficient electrical quantity of the bias power 510b is still below the bias power threshold 506 at t2 512, the Power Receiver might refrain from entering the power state. The Power Receiver might present a fault indication at a third time (shown as t3 514) via a user interface of the Power Receiver or the Power Transmitter. The fault indication can inform an end user of the Power Receiver that the Power Receiver cannot enter the power state. In some implementations, the fault indication can indicate that the insufficient electrical quantity of the bias power 510b is below the bias power threshold 506, or alternatively, the fault indication might be an indicator associated with a communication error or general fault of the wireless power system.

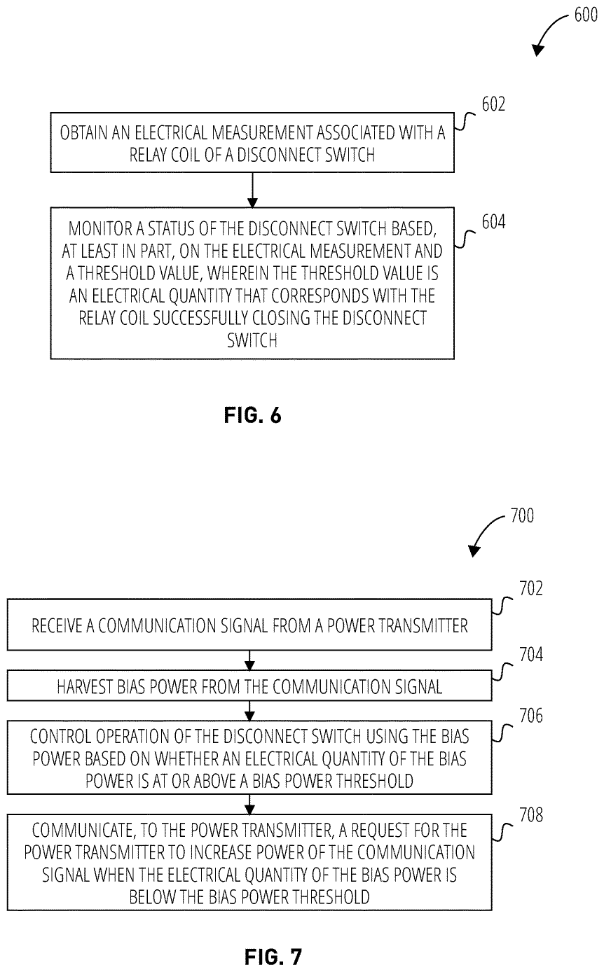

FIG. 6 illustrates a flow chart with example operations 600 of a Power Receiver. For example, the operations 600 might be performed by any of the Power Receivers 118 or 200 described with reference to FIG. 1 and FIG. 2, respectively. In block 602, the Power Receiver obtains an electrical measurement associated with a relay coil of a disconnect switch. In block 604, the Power Receiver monitors a status of the disconnect switch based, at least in part, on the electrical measurement and a threshold value, wherein the threshold value is an electrical quantity that corresponds with the relay coil successfully closing the disconnect switch.

In some implementations, the electrical measurement is a relay coil current of the relay coil, and the threshold value is a holding current of the relay coil. In some other implementations, the electrical measurement is a control voltage applied to the relay coil, and the threshold value is an activation voltage of the relay coil. In some other implementations, the electrical measurement might be a relay coil current that is estimated based on the control voltage and a calculated or known resistance of the relay coil.

FIG. 7 illustrates another flow chart with example operations 700 of a Power Receiver. For example, the operations 700 might be performed by any of the Power Receivers 118 or 200 described with reference to FIG. 1 and FIG. 2, respectively. In block 702, the Power Receiver receives a communication signal from a Power Transmitter. In block 704, the Power Receiver harvests bias power from the communication signal. In block 706, the Power Receiver controls operation of the disconnect switch using the bias power based on whether an electrical quantity of the bias power is at or above a bias power threshold. In block 708, the Power Receiver communicates, to the Power Transmitter, a request for the Power Transmitter to increase power of the communication signal when the electrical quantity of the bias power is below the bias power threshold.

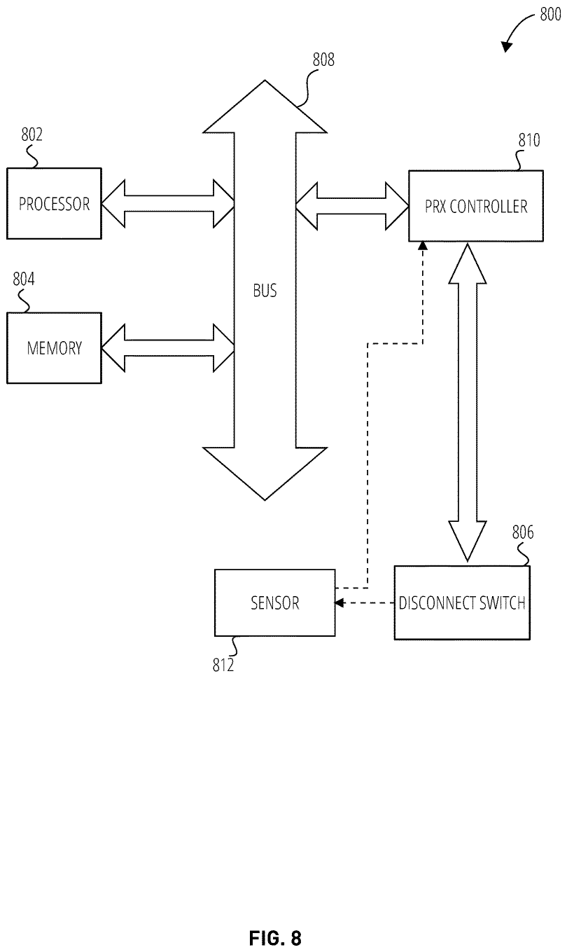

FIG. 8 illustrates a block diagram of an example apparatus for use in a wireless power system. In some implementations, the apparatus 800 may be a wireless power apparatus (such as any of the Power Receivers 118, 200, described with reference to FIG. 1 and FIG. 2, respectively. The apparatus 800 can include a processor 802 (possibly including multiple processors, multiple cores, multiple nodes, or implementing multi-threading, among other examples). The apparatus 800 also can include a memory 804. The memory 804 may be system memory or any one or more of the possible realizations of computer-readable media described herein. The apparatus 800 also can include a bus 808 (such as PCI, ISA, PCI-Express, HyperTransport®, InfiniBand®), NuBus,® AHB, AXI, etc.).

The apparatus 800 may include one or more PRx controllers 810. In some implementations, the PRx controller 810 can be distributed within the processor 802, the memory 804, and the bus 808. The PRx controller 810 may perform some or all of the operations described herein. For example, the PRx controller 810 may implement the operations described with reference to any one of FIG. 1 through FIG. 7, or any combination thereof.

The memory 804 can include computer instructions executable by the processor 802 to implement the functionality of the implementations described herein. Any one of these functionalities may be partially (or entirely) implemented in hardware or on the processor 802. For example, the functionality may be implemented with an application specific integrated circuit, in logic implemented in the processor 802, in a co-processor on a peripheral device or card, etc. Further, realizations may include fewer or additional components not illustrated in FIG. 8. The processor 802, the memory 804, and the PRx controller 810 may be coupled to the bus 808. Although illustrated as being coupled to the PRx controller 810. the memory 804 may be coupled to the processor 802.

In some implementations, the apparatus 800 includes a disconnect switch 806. The disconnect switch 806 might include a relay coil and a circuit connecting component. The PRx controller 810 might operate the disconnect switch 806 in accordance with the operating state of the wireless power system. The apparatus 800 further includes a sensor 812 configured to measure an electrical measurement of the relay coil of the disconnect switch 806. The PRx controller 810 is configured to monitor the status of the disconnect switch 806 based on the electrical measurement obtained by the sensor 812. Furthermore, the PRx controller 810 might be configured to implement the operations described with reference to any one of FIG. 1 through FIG. 7, or any combination thereof. For example, the PRx controller 810 might coordinate with a Power Transmitter to ensure that a bias power harvested from a communication signal is sufficient to satisfy a bias power threshold. The bias power threshold might be derived from a threshold value (such as the holding current) of the relay coil in the disconnect switch 806. The PRx controller 810 can refrain from transitioning to a power state if the bias power is insufficient to satisfy the bias power threshold.

FIG. 1 through FIG. 8 and the operations described herein are examples meant to aid in understanding example implementations and should not be used to limit the potential implementations or limit the scope of the claims. Some implementations may perform additional operations, fewer operations, operations in parallel or in a different order, and some operations differently.

The foregoing disclosure provides illustration and description but is not intended to be exhaustive or to limit the aspects to the precise form disclosed. Modifications and variations may be made in consideration of the above disclosure or may be acquired from practice of the aspects. While the aspects of the disclosure have been described in terms of various examples, any combination of aspects from any of the examples is also within the scope of the disclosure. The examples in this disclosure are provided for pedagogical purposes. Alternatively, or in addition to the other examples described herein, examples include any combination of the following implementation options (identified as clauses for reference).

### Clauses

Clause 1. A method of a Power Receiver, including: obtaining an electrical measurement associated with a relay coil of a disconnect switch; monitoring a status of the disconnect switch based, at least in part, on the electrical measurement and a threshold value, where the threshold value is an electrical quantity that corresponds with the relay coil successfully closing the disconnect switch.

Clause 2. The method of clause 1, where monitoring the status includes: determining that the disconnect switch is open when the electrical measurement is below the threshold value; and determining that the disconnect switch is closed when the electrical measurement is at or above the threshold value.

Clause 3. The method of clause 1 or 2, further including, before a power state: sending a switch control signal to close the disconnect switch, where the switch control signal energizes the relay coil of the disconnect switch; and verifying that the disconnect switch is closed based on the electrical measurement being at or above the threshold value after sending the switch control signal.

Clause 4. The method of any one of clauses 1 to 3, further including: continuously or periodically comparing the electrical measurement to the threshold value during the power state.

Clause 5. The method of any one of clauses 1 to 4, further including: receiving a communication signal from a Power Transmitter; harvesting bias power from the communication signal; and if an electrical quantity of the bias power is above a bias power threshold, powering the relay coil using the bias power as part of a transition to a power state.

Clause 6. The method of clause 5, where the bias power threshold is a voltage or current sufficient to produce the threshold value.

Clause 7. The method of clause 5 or 6, further including: measuring the electrical quantity of the bias power; communicating, to the Power Transmitter, a request for the Power Transmitter to increase power of the communication signal when the electrical quantity of the bias power is below the bias power threshold.

Clause 8. The method of any one of clauses 5 to 7, further including: receiving a Power Transmitter status (PTx status) indication that indicates the Power Transmitter is using a maximum power for the communication signal; determining that the electrical quantity of the bias power is below the bias power threshold; and indicating a fault condition via a user interface of the Power Receiver.

Clause 9. The method of any one of clauses 5 to 8, further including: refraining from transitioning to the power state while the electrical quantity of the bias power is below the bias power threshold.

Clause 10. The method of any one of clauses 1 to 9, where the electrical measurement is a relay coil current of the relay coil, and the threshold value is a holding current of the relay coil.

Clause 11. The method of any one of clauses 1 to 9, where the electrical measurement is a control voltage applied to the relay coil, and the threshold value is an activation voltage of the relay coil.

Clause 12. A method of a Power Receiver having a disconnect switch, the method including: receiving a communication signal from a Power Transmitter; harvesting bias power from the communication signal; controlling operation of the disconnect switch using the bias power based on whether an electrical quantity of the bias power is at or above a bias power threshold; and communicating, to the Power Transmitter, a request for the Power Transmitter to increase power of the communication signal when the electrical quantity of the bias power is below the bias power threshold.

Clause 13. The method of clause 12, where the bias power threshold is associated with a power or voltage requirement to satisfy a threshold value of a switch control signal applied to a relay coil of the disconnect switch to successfully close the disconnect switch.

Clause 14. The method of clause 12 or 13, further including: receiving a Power Transmitter status (PTx status) indication that indicates the Power Transmitter is using a maximum power for the communication signal; determining that the electrical quantity of the bias power is below the bias power threshold; and indicating a fault condition via a user interface of the Power Receiver.

Clause 15. The method of any one of clauses 12 to 14, further including: refraining from transitioning to the power state while the electrical quantity of the bias power is below the bias power threshold.

Clause 16. The method of any one of clauses 12 to 15, including: obtaining an electrical measurement associated with a relay coil of the disconnect switch: monitoring a status of the disconnect switch based, at least in part, on the electrical measurement and a threshold value, where the threshold value is an electrical quantity that corresponds with the relay coil successfully closing the disconnect switch.

Clause 17. The method of clause 16, where monitoring the status includes: determining that the disconnect switch is open when the electrical measurement is below the threshold value; and determining that the disconnect switch is closed when the electrical measurement is at or above the threshold value.

Clause 18. The method of clause 16 or 17, further including, before a power state: sending a switch control signal to close the disconnect switch, where the switch control signal energizes the relay coil of the disconnect switch; and verifying that the disconnect switch is closed based on the electrical measurement being at or above the threshold value after sending the switch control signal.

Clause 19. The method of any one of clauses 16 to 18, further including: continuously or periodically comparing the electrical measurement to the threshold value during the power state.

Clause 20. A Power Receiver, including: a disconnect switch having a relay coil and a circuit connecting component: a current sensor configured to obtain an electrical measurement associated with the relay coil; and a controller configured to implement any one of clauses 1 to 19.

Another innovative aspect of the subject matter described in this disclosure can be implemented as a computer-readable medium having stored therein instructions which, when executed by a processor, causes the processor to perform any one of the above-mentioned functionalities.

Another innovative aspect of the subject matter described in this disclosure can be implemented as a system having means for implementing any one of the above-mentioned functionalities.

Another innovative aspect of the subject matter described in this disclosure can be implemented as an apparatus having one or more processors configured to perform one or more operations from any one of the above-mentioned methods.

As used herein, a phrase referring to “at least one of” or “one or more of” a list of items refers to any combination of those items, including single members. For example, “at least one of: a, b, or c” is intended to cover the possibilities of: a only, b only, c only, a combination of a and b, a combination of a and c, a combination of b and c, and a combination of a and b and c.

The various illustrative components, logic, logical blocks, modules, circuits, operations and algorithm processes described in connection with the implementations disclosed herein may be implemented as electronic hardware, firmware, software, or combinations of hardware, firmware or software, including the structures disclosed in this specification and the structural equivalents thereof. The interchangeability of hardware, firmware and software has been described generally, in terms of functionality, and illustrated in the various illustrative components, blocks, modules, circuits and processes described above. Whether such functionality is implemented in hardware, firmware or software depends upon the particular application and design constraints imposed on the overall system.

The hardware and data processing apparatus used to implement the various illustrative components, logics, logical blocks, modules and circuits described in connection with the aspects disclosed herein may be implemented or performed with a general purpose single-or multi-chip processor, a digital signal processor (DSP), an application specific integrated circuit (ASIC), a field programmable gate array (FPGA) or other programmable logic device (PLD), discrete gate or transistor logic, discrete hardware components, or any combination thereof designed to perform the functions described herein. A general-purpose processor may be a microprocessor, or any conventional processor, controller, microcontroller, or state machine. A processor also may be implemented as a combination of computing devices, for example, a combination of a DSP and a microprocessor, multiple microprocessors, one or more microprocessors in conjunction with a DSP core, or any other such configuration. In some implementations, particular processes, operations and methods may be performed by circuitry that is specific to a given function.

As described above, some aspects of the subject matter described in this specification can be implemented as software. For example, various functions of components disclosed herein, or various blocks or steps of a method, operation, process or algorithm disclosed herein can be implemented as one or more modules of one or more computer programs. Such computer programs can include non-transitory processor-executable or computer-executable instructions encoded on one or more tangible processor-readable or computer-readable storage media for execution by, or to control the operation of, a data processing apparatus including the components of the devices described herein. By way of example, and not limitation, such storage media may include RAM, ROM, EEPROM, CD-ROM or other optical disk storage, magnetic disk storage or other magnetic storage devices, or any other medium that may be used to store program code in the form of instructions or data structures. Combinations of the above should also be included within the scope of storage media.

Various modifications to the implementations described in this disclosure may be readily apparent to persons having ordinary skill in the art, and the generic principles defined herein may be applied to other implementations without departing from the scope of this disclosure. Thus, the claims are not intended to be limited to the implementations shown herein but are to be accorded the widest scope consistent with this disclosure, the principles and the novel features disclosed herein.

Additionally, various features that are described in this specification in the context of separate implementations also can be implemented in combination in a single implementation. Conversely, various features that are described in the context of a single implementation also can be implemented in multiple implementations separately or in any suitable subcombination. As such, although features may be described above as acting in particular combinations, and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one or more example processes in the form of a flowchart or flow diagram. However, other operations that are not depicted can be incorporated in the example processes that are schematically illustrated. For example, one or more additional operations can be performed before, after, simultaneously, or between any of the illustrated operations. In some circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products.

1. A method of a Power Receiver, comprising:
obtaining an electrical measurement associated with a relay coil of a disconnect switch;
determining that the the disconnect switch is closed when the electrical measurement being at or above a threshold value, wherein the threshold value is an electrical quantity that corresponds with the relay coil successfully closing the disconnect switch; and
verifying that the disconnect switch is closed before a power transfer phase with a Power Transmitter.

2. The method of claim 1, further comprising:
determining that the disconnect switch is closed when the electrical measurement is at or above the threshold value.

3. The method of claim 1, further comprising, before the power transfer phase:
sending a switch control signal to close the disconnect switch, wherein the switch control signal energizes the relay coil of the disconnect switch; and
verifying that the disconnect switch is closed after sending the switch control signal.

4. The method of claim 1, further comprising:
continuously or periodically comparing the electrical measurement to the threshold value during the power transfer phase.

5. The method of claim 1, further comprising:
receiving a communication signal from a Power Transmitter;
harvesting bias power from the communication signal; and
if an electrical quantity of the bias power is above a bias power threshold, powering the relay coil using the bias power as part of a transition to the power transfer phase.

6. (canceled)

7. The method of claim 5, further comprising:
measuring the electrical quantity of the bias power; and
communicating, to the Power Transmitter, a request for the Power Transmitter to increase power of the communication signal when the electrical quantity of the bias power is below the bias power threshold.

8. The method of claim 5, further comprising:
receiving a Power Transmitter status (PTx status) indication that indicates the Power Transmitter is using a maximum power for the communication signal;
determining that the electrical quantity of the bias power is below the bias power threshold; and
indicating a fault condition via a user interface of the Power Receiver.

9. The method of claim 5, further comprising:
refraining from transitioning to the power transfer phase while the electrical quantity of the bias power is below the bias power threshold.

10. The method of claim 1, wherein
the electrical measurement is a relay coil current of the relay coil, and
the threshold value is a holding current of the relay coil.

11. The method of claim 1, wherein
the electrical measurement is a control voltage applied to the relay coil, and
the threshold value is an activation voltage of the relay coil.

12. A method of a Power Receiver having a disconnect switch, the method comprising:
receiving a communication signal from a Power Transmitter;
harvesting bias power from the communication signal;
controlling operation of the disconnect switch using the bias power based on whether an electrical quantity of the bias power is at or above a bias power threshold; and
communicating, to the Power Transmitter, a request for the Power Transmitter to increase power of the communication signal when the electrical quantity of the bias power is below the bias power threshold.

13. The method of claim 12,
wherein the bias power threshold is associated with a power or voltage requirement to satisfy a threshold value of a switch control signal applied to a relay coil of the disconnect switch to successfully close the disconnect switch.

14. The method of claim 12, further comprising:
receiving a Power Transmitter status (PTx status) indication that indicates the Power Transmitter is using a maximum power for the communication signal;
determining that the electrical quantity of the bias power is below the bias power threshold; and
indicating a fault condition via a user interface of the Power Receiver.

15. The method of claim 12, further comprising:
refraining from transitioning to the power transfer phase while the electrical quantity of the bias power is below the bias power threshold.

16. The method of claim 12, comprising:
obtaining an electrical measurement associated with a relay coil of the disconnect switch; and
monitoring a status of the disconnect switch based, at least in part, on the electrical measurement and a threshold value, wherein the threshold value is an electrical quantity that corresponds with the relay coil successfully closing the disconnect switch.

17. The method of claim 16, wherein monitoring the status includes:
determining that the disconnect switch is open when the electrical measurement is below the threshold value; and
determining that the disconnect switch is closed when the electrical measurement is at or above the threshold value.

18. The method of claim 16, further comprising, before a power transfer phase:
sending a switch control signal to close the disconnect switch, wherein the switch control signal energizes the relay coil of the disconnect switch; and
verifying that the disconnect switch is closed based on the electrical measurement being at or above the threshold value after sending the switch control signal.

19. The method of claim 18, comprising:
continuously or periodically comparing the electrical measurement to the threshold value during the power transfer phase.

20. A Power Receiver, comprising:
a disconnect switch having a relay coil and a circuit connecting component;
a current sensor configured to obtain an electrical measurement associated with the relay coil; and
a controller configured to
determine that the disconnect switch is closed when based, at least in part, on the electrical measurement being at or above and a threshold value, wherein the threshold value is an electrical quantity that corresponds with the relay coil successfully closing the disconnect switch; and
verify that the disconnect switch is closed before a power transfer phase with a Power Transmitter.

21. The Power Receiver of claim 20, further comprising:
a communication unit to:
receive a communication signal from the Power Transmitter,
harvest bias power from the communication signal; and
the controller further configured to:
control operation of the disconnect switch using the bias power based on whether an electrical quantity of the bias power is at or above a bias power threshold; and
cause the communication unit to communicate, to the Power Transmitter, a request for the Power Transmitter to increase power of the communication signal when the electrical quantity of the bias power is below the bias power threshold.
